(19) United States
(12) Patent Application Publication
(10) Pub. No.: US 2024/0213031 A1
(43) Pub. Date: Jun. 27, 2024

(54) ETCHING METHOD AND PLASMA PROCESSING APPARATUS

(71) Applicant: Tokyo Electron Limited, Tokyo (JP)

(72) Inventors: Atsuki HASHIMOTO, Hwaseong-si (KR); Sho SAITOH, Kurokawa-gun (JP); Yoshimitsu KON, Kurokawa-gun (JP)

(73) Assignee: Tokyo Electron Limited, Tokyo (JP)

(21) Appl. No.: 18/395,879

(22) Filed: Dec. 26, 2023

(30) Foreign Application Priority Data
Dec. 27, 2022 (JP) 2022-209596
Nov. 6, 2023 (JP) 2023-189189

(51) Int. Cl. H01L 21/311; H01J 37/32; H01L 21/02

(52) U.S. Cl. CPC H01L 21/31116; H01L 21/02164; H01L 21/0217; H01L 21/02175; H01J 37/32449; H01J 37/32807; H01J 2237/3346

(57) ABSTRACT

An etching method includes (a) providing a substrate including a first region and a second region below the first region, the first region containing a first material and including an opening, the second region containing a second material different from the first material, the second material containing silicon; (b) forming a metal-containing deposition on the first region by using first plasma generated from a first process gas containing halogen, metal, and at least one of carbon or hydrogen; and (c) after (b), etching the second region via the opening by using second plasma generated from a second process gas different from the first process gas.

### CROSS-REFERENCE TO RELATED APPLICATIONS

This application is based upon and claims the benefit of priority from Japanese Patent Application No. 2022-209596, filed on Dec. 27, 2022, and Japanese Patent Application No. 2023-189189, filed on Nov. 6, 2023, the entire contents of each are incorporated herein by reference.

### BACKGROUND

### Field

An exemplary embodiment of the present disclosure relates to an etching method and a plasma processing apparatus.

### Description of the Related Art

Japanese Unexamined Patent Publication No. 2016-157793 discloses a method of selectively etching a first region formed of silicon oxide with respective to a second region formed of silicon nitride by plasma processing on a substrate. The second region has a recess. The first region is provided to fill the recess and cover the second region. The first region is etched by plasma generated from a process gas containing fluorocarbon.

### SUMMARY

In an exemplary embodiment, an etching method includes (a) providing a substrate including a first region and a second region below the first region, the first region containing a first material and including an opening, the second region containing a second material different from the first material, the second material containing silicon; (b) forming a metal-containing deposition on the first region by using first plasma generated from a first process gas containing halogen, metal, and at least one of carbon or hydrogen; and (c) after (b), etching the second region via the opening by using second plasma generated from a second process gas different from the first process gas.

### BRIEF DESCRIPTION OF THE DRAWINGS

FIG. 1 is a schematic diagram illustrating a plasma processing system according to an exemplary embodiment.

FIG. 2 is a schematic diagram illustrating a plasma processing apparatus according to the exemplary embodiment.

FIG. 3 is a flowchart illustrating an etching method according to the exemplary embodiment.

FIG. 4 is a partially enlarged view of an example of a substrate to which the method of FIG. 3 may be applied.

FIG. 5 is a cross-sectional view illustrating a step of the etching method according to the exemplary embodiment.

FIG. 6 is a cross-sectional view illustrating another step of the etching method according to the exemplary embodiment.

FIG. 7 is a cross-sectional view illustrating still another step of the etching method according to the exemplary embodiment.

FIG. 8 is a cross-sectional view illustrating still yet another step of the etching method according to the exemplary embodiment.

FIG. 9 is a flowchart illustrating an etching method according to another exemplary embodiment.

FIG. 10 is a cross-sectional view of an example of a substrate to which the method of FIG. 9 may be applied.

FIG. 11 is a cross-sectional view illustrating the etching method according to the other exemplary embodiment.

FIG. 12 is a cross-sectional view illustrating another step of the etching method according to the other exemplary embodiment.

FIG. 13 is a cross-sectional view illustrating still another step of the etching method according to the other exemplary embodiment.

FIG. 14 is a cross-sectional view illustrating still yet another step of the etching method according to the other exemplary embodiment.

FIG. 15 is a cross-sectional view illustrating still yet another step of the etching method according to the other exemplary embodiment.

FIG. 16 is a cross-sectional view illustrating still yet another step of the etching method according to the other exemplary embodiment.

FIG. 17 is a cross-sectional view illustrating still yet another step of the etching method according to the other exemplary embodiment.

FIG. 18 is a cross-sectional view illustrating still yet another step of the etching method according to the other exemplary embodiment.

### DETAILED DESCRIPTION

Hereinafter, various exemplary embodiments will be described in detail with reference to the drawings. In the drawing, the same or equivalent portions are denoted by the same reference symbols.

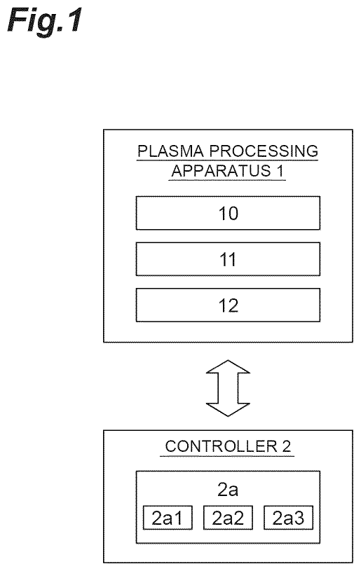

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SDS), or any combination thereof. The communication interface 2a3 can communicate with the plasma processing apparatus 1 via a communication line, such as a local area network (LAN).

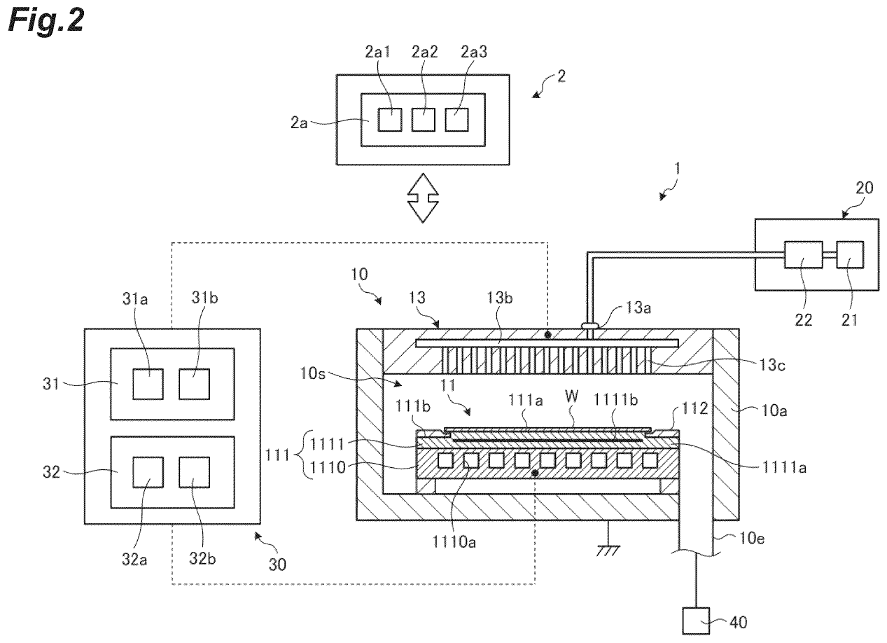

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

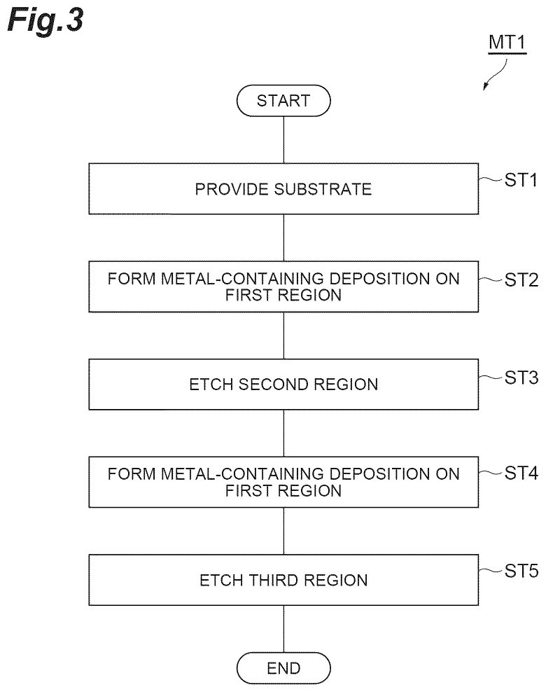

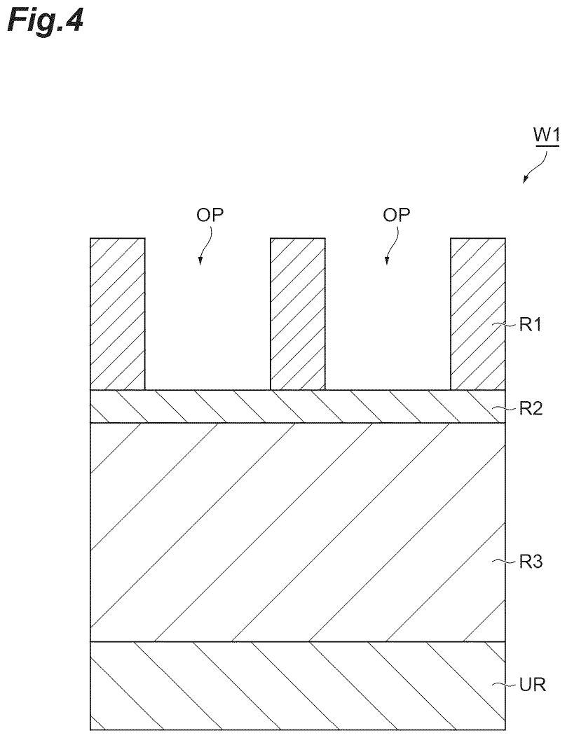

FIG. 3 is a flowchart illustrating an etching method according to an exemplary embodiment. An etching method MT1 (referred to as a “method MT1” below) illustrated in FIG. 3 may be performed by the plasma processing apparatus 1 in an embodiment. The method MT1 may be applied to a substrate W1 in FIG. 4.

FIG. 4 is a cross-sectional view of a substrate as an example to which the method in FIG. 3 may be applied. As illustrated in FIG. 4, in the embodiment, the substrate W1 includes a first region R1 and a second region R2. The substrate W1 may further include a third region. The first region R1 may function as a mask. The first region R1 has at least one opening OP. The at least one opening OP may be a hole or a slit. The first region R1 may have a plurality of openings OP. The width of the first region R1 located between a plurality of adjacent openings OP may be 20 nm or less, or may be 10 nm or less. The second region R2 may be located below the first region R1. The third region R3 may be located below the second region R2. The third region R3 may be located below the first region R1. The substrate W1 may further include an underlying region UR. The underlying region UR may be located below the third region R3. In the substrate W1, the first region R1, the second region R2, the third region R3, and the underlying region UR may be arranged in the downward direction in this order.

The first region R1 contains a first material. The first material may contain metal or silicon. The metal may contain tungsten or molybdenum. Silicon may include polysilicon. The first region R1 may be a polysilicon film. The first region R1 may be a boron-containing silicon film, a tungsten film, a tungsten silicide film, or a molybdenum film. The first region R1 may have a thickness of 500 nm or more.

The second region R2 contains a second material. The second material is different from the first material and contains silicon. The second material may contain nitrogen in addition to silicon. The second material may contain silicon nitride (SiNₓ). x is a positive real number. The second region R2 may be a silicon nitride film. The second region R2 may have a thickness of 150 nm or more. The second material may contain oxygen in addition to silicon. The second material may contain silicon oxide (SiOₓ). x is a positive real number. The second region R2 may be a silicon oxide film. The second region R2 may have a thickness of 800 nm or less.

The third region R3 contains a third material. The third material is different from the first material and the second material and contains silicon. The third material may contain oxygen in addition to silicon. The third material may contain silicon oxide (SiOₓ). x is a positive real number. The third region R3 may be a silicon oxide film. The third region may have a thickness of 100 nm or more, a thickness of 200 nm or more, or a thickness of 300 nm or more. The third region may have a thickness of 800 nm or less, or may have a thickness of 400 nm or less. When the second material contains silicon and oxygen, the third region R3 may not be provided.

The underlying region UR may contain metal or silicon. The underlying region UR may contain silicon nitride (SiNₓ), silicon oxide (SiOₓ), or silicon oxynitride (SiON). The underlying region UR may include at least one of a silicon nitride film, a silicon oxide film, or a silicon oxynitride film.

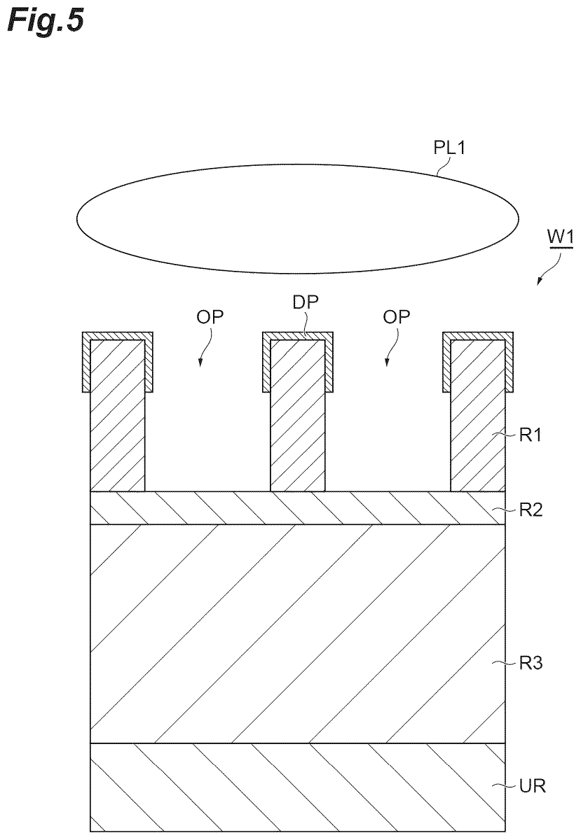

A method MT1 will be described below with reference to FIGS. 3 to 8 by using, as an example, the case where the method MT1 is applied to the substrate W1 by using a plasma processing apparatus 1 in the above-described embodiment. FIGS. 5 to 8 are cross-sectional views illustrating steps of an etching method according to the exemplary embodiment. When the plasma processing apparatus 1 is used, the method MT1 may be performed in the plasma processing apparatus 1 in a manner that a controller 2 controls each unit of the plasma processing apparatus 1. In the method MT1, as illustrated in FIG. 2, a substrate W1 is processed instead of a substrate W on a substrate support 11 disposed in a plasma processing chamber 10.

As illustrated in FIG. 3, the method MT1 includes Steps ST1 to ST5. Steps ST1 to ST5 may be performed in order. The method MT1 may not include Step ST4 or may not include Step ST5.

### (Step ST1)

In Step ST1, a substrate W1 illustrated in FIG. 4 is provided. The substrate W1 may be supported by the substrate support 11 in the plasma processing chamber 10.

### (Step ST2)

In Step ST2, as illustrated in FIG. 5, a metal-containing deposition DP is formed on the first region R1 by using first plasma PL1 generated from a first process gas. The supply of the first process gas may be stopped when Step ST2 is ended. The metal-containing deposition DP may be preferentially formed on the first region R1 compared to the second region R2. Here, “the metal-containing deposition DP may be preferentially formed on the first region R1 compared to the second region R2” means, for example, that the thickness of the metal-containing deposition DP on the first region R1 is greater than the thickness of the metal-containing deposition DP on the second region R2. More specifically, for example, “the metal-containing deposition DP may be preferentially formed on the first region R1 compared to the second region R2” means that a thickness of the metal-containing deposition DP on the second region R2 is equal to or less than 50% of the thickness of the metal-containing deposition DP on the first region R1. Deposition may be performed as follows. First, a gas supply 20 supplies the first process gas into the plasma processing chamber 10. Then, a plasma generator 12 generates the first plasma PL1 from the first process gas in the plasma processing chamber 10. The controller 2 controls the gas supply 20 and the plasma generator 12 such that the metal-containing deposition DP is formed on the first region R1.

The first process gas contains halogen, metal, and at least one of carbon or hydrogen. Halogen may be at least one element selected from the group consisting of fluorine, chlorine, and bromine. The first process gas may contain a metal-containing gas and at least one of a carbon-containing gas or a hydrogen-containing gas. The halogen may be contained in the carbon-containing gas, may be contained in the hydrogen-containing gas, or may be contained in the metal-containing gas. The metal contained in the first process gas may contain at least one of molybdenum or tungsten.

The metal-containing gas that may be contained in the first process gas may include at least one of a molybdenum halide gas or a tungsten halide gas. The molybdenum halide gas may include at least one selected from the group consisting of a MoF₃ gas, a MoF₅ gas, a MoF₆ gas, a MoCl₆ gas, a MoBr₆ gas, a MoCl₂ gas, a MoBr₂ gas, a MoCl₅ gas, a Mo₃Br₅ gas, a Mo₆Cl₈ gas, a Mo₆Cl₁₂ gas, a Mo₆Br₁₂ gas, and a Mo₆Cl₁₄ gas. The tungsten halide gas may include at least one selected from the group consisting of a WF₆ gas, a WCl₆ gas, a WBr₆ gas, and a WF₅Cl gas.

The flow rate ratio of the metal-containing gas may be less than the flow rate ratio of at least one of the carbon-containing gas or the hydrogen-containing gas. In the present disclosure, the flow rate ratio of each gas is the proportion (vol %) of the flow rate of each gas to the total flow rate of the process gas.

The proportion of the flow rate of the metal-containing gas to the total flow rate of the first process gas may be 10 vol % or less or may be 5 vol % or less. Alternatively, the proportion of the flow rate of the metal-containing gas to the total flow rate of the first process gas may be 0.5 vol % or more and 3 vol % or less.

The carbon-containing gas that may be contained in the first process gas may include at least one of a CH₄ gas, a C₂H₂ gas, a C₂H₄ gas, a CH₃F gas, a CH₂F₂ gas, a CHF₃ gas, or a CO gas.

The hydrogen-containing gas that may be included in the first process gas may include at least one of a H₂ gas, a SiH₄ gas, or a NH₃ gas.

The first process gas may contain at least one of a hydrocarbon (CₓH_{y}) gas or a hydrofluorocarbon (CₓH_{y}F_{z}) gas. x, y, and z are integers of 1 or more. The hydrocarbon gas may include at least one of a CH₄ gas, a C₂H₂ gas, a C₂H₄ gas, a C₂H₆ gas, a C₃H₆ gas, or a C₃H₈ gas. The hydrofluorocarbon gas may include at least one of CH₂F₂, a CHF₃ gas, a CH₃F gas, or a C₃H₂F₄ gas.

The first process gas may contain, for example, a noble gas such as an argon gas, a helium gas, a xenon gas, or a neon gas. The first process gas may contain, for example, a nitrogen (N₂) gas. The flow rate ratio of the noble gas may be more than the flow rate ratio of at least one of the carbon-containing gas or the hydrogen-containing gas.

The duration of Step ST2 may be 1 second or longer or 10 seconds or longer. The duration of Step ST2 may be 1000 seconds or shorter or 100 seconds or shorter.

In Step ST2, the temperature of the substrate support 11 may be 50° C. or higher, 100° ° C. or higher, higher than 100° C., 120° C. or higher, 130° C. or higher, higher than 130° C., 140° C. or higher, or 150° C. or higher. In addition, the temperature of the substrate support 11 may be 250° C. or lower, 220° C. or lower, or 200° C. or lower.

In Step ST2, the pressure in the plasma processing chamber 10 may be 10 mTorr (1.3 Pa) or more. In addition, the pressure in the plasma processing chamber 10 may be 100 mTorr (13 Pa) or less, or may be 50 mTorr (6.7 Pa) or less.

In Step ST2, RF power may be applied to the facing electrode that faces the substrate support 11. The RF power may be 100 W or more and 1000 W or less, 200 W or more and 800 W or less, and may be 300 W or more and 500 W or less. The frequency of the RF power may be 27 MHz or more and 100 MHz or less.

In Step ST2, bias power may or may not be applied to the substrate support 11 (for example, an electrode in a body 111). The bias power in Step ST2 may be less than the bias power in Step ST3 and may be less than 100 W.

The metal-containing deposition DP may be formed on the upper surface of the first region R1. The metal-containing deposition DP may be formed on a side wall defining the opening OP in the first region R1. The metal-containing deposition DP may be formed in an upper portion of the side wall defining the opening OP or may not be formed in the upper portion of the side wall defining the opening OP. The metal-containing deposition DP contains metal contained in the first process gas. The metal-containing deposition DP may contain at least one of molybdenum or tungsten. The metal-containing deposition DP may be a molybdenum-containing layer or a tungsten-containing layer.

The metal-containing deposition DP may contain carbon. The metal-containing deposition DP may contain a tungsten carbide (WCₓ). x is a positive real number. When Step ST2 is ended, the maximum value of the thickness of the metal-containing deposition DP may be 5 nm or more.

While not being bound by theory, the metal-containing deposition DP may be formed as follows. When the first process gas contains carbon and a metal (for example, tungsten or molybdenum), active species containing metal in the first plasma PL1 react with active species containing carbon in the first plasma PL1. As a result, a metal-containing deposition containing a metal carbide (MCₓ) is deposited on the upper surface of the first region R1. Alternatively, when the first process gas contains hydrogen and metal, active species containing halogen in the first plasma PL1 is scavenged by active species containing hydrogen in the first plasma PL1. As a result, a metal-containing deposition derived from the active species containing metal remaining in the first plasma PL1 is deposited on the upper surface of the first region R1. When the first process gas contains both carbon and hydrogen, the reaction between metal and carbon and the scavenging of halogen by hydrogen proceed together.

### (Step ST3)

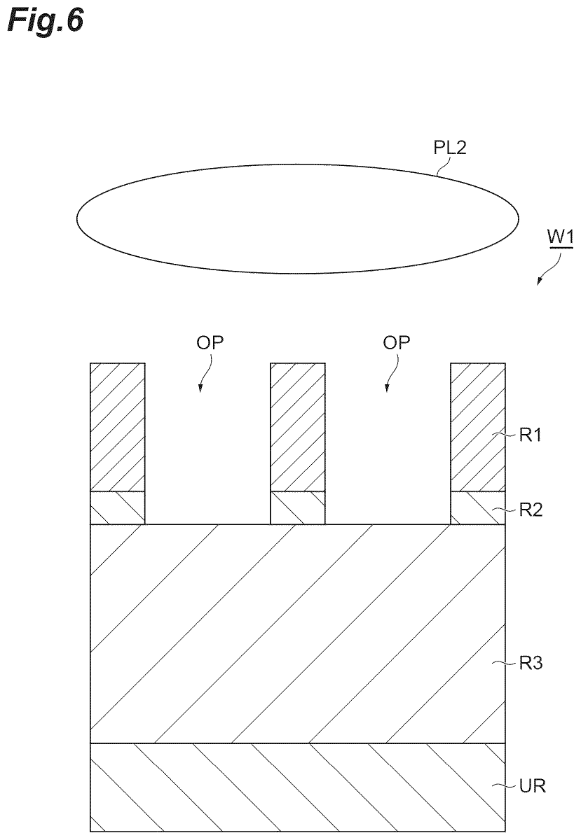

In Step ST3, as illustrated in FIG. 6, the second region R2 is etched via the opening OP by using second plasma PL2 generated from the second process gas. As a result, an opening is formed in the second region R2. The supply of the second process gas may be stopped when Step ST3 is ended. Step ST3 may be performed as follows. First, the gas supply 20 supplies the second process gas into the plasma processing chamber 10. Then, the plasma generator 12 generates the second plasma PL2 from the second process gas in the plasma processing chamber 10. The controller 2 controls the gas supply 20 and the plasma generator 12 such that the second region R2 is etched with the second plasma PL2.

The second process gas is different from the first process gas. The second process gas may contain a hydrogen-containing gas. Examples of the hydrogen-containing gas include a hydrofluorocarbon gas. An example of the hydrofluorocarbon gas is the same as the example of the hydrofluorocarbon gas that may be contained in the first process gas. The second process gas may further contain a fluorine-containing gas. Examples of the fluorine-containing gas may include at least one of a fluorocarbon (CₓF_{y}) gas or an NF₃ gas. x and y are integers of 1 or more. The fluorocarbon gas may include at least one of a CF₄ gas, a C₃F₆ gas, a C₃F₈ gas, a C₄F₆ gas, or a C₄F₈ gas.

In Step ST3, the temperature of the substrate support 11 may be 10° C. or higher and 100° ° C. or lower.

In Step ST3, the metal-containing deposition DP may be removed. In Step ST3, a portion of the first region R1 may also be removed.

### (Step ST4)

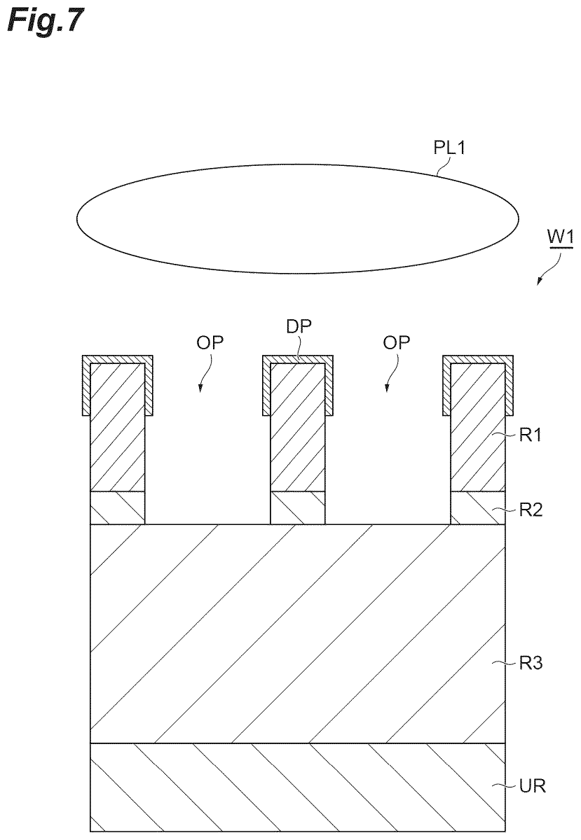

In Step ST4, as illustrated in FIG. 7, a metal-containing deposition DP is formed on the first region R1 by using first plasma PL1 generated from a first process gas. The supply of the first process gas may be stopped when Step ST4 is ended. Step ST4 may be performed in the similar manner as Step ST2.

### (Step ST5)

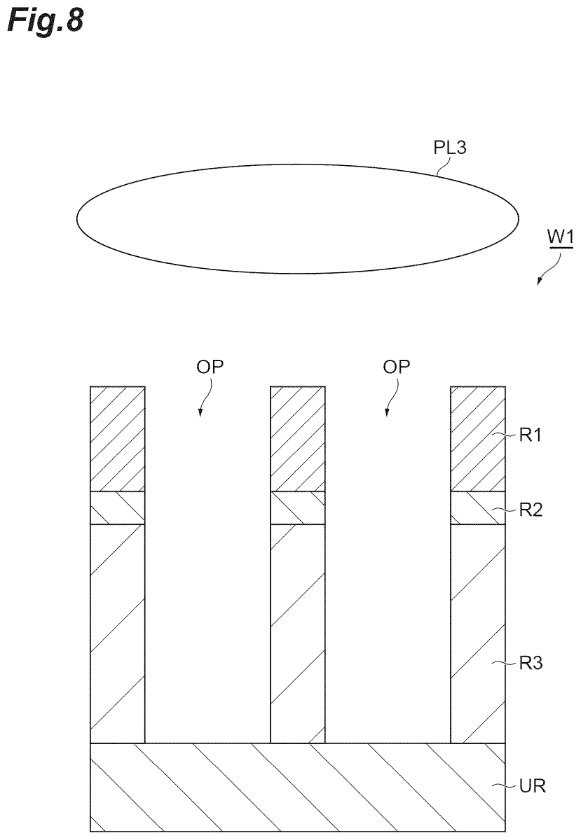

In Step ST5, as illustrated in FIG. 8, the third region R3 is etched via the opening OP by using third plasma PL3 generated from a third process gas. As a result, an opening is formed in the third region R3. The supply of the third process gas may be stopped when Step ST5 is ended. Step ST5 may be performed as follows. First, the gas supply 20 supplies the third process gas into the plasma processing chamber 10. Then, the plasma generator 12 generates the third plasma PL3 from the third process gas in the plasma processing chamber 10. The controller 2 controls the gas supply 20 and the plasma generator 12 such that the third region R3 is etched with the third plasma PL3.

The third process gas is different from the first process gas and the second process gas. The third process gas does not need to contain the hydrogen-containing gas. An example of the hydrogen-containing gas is the same as the example of the hydrogen-containing gas that may be contained in the second process gas. The third process gas may contain a fluorine-containing gas. An example of the fluorine-containing gas is the same as the example of the fluorine-containing gas that may be contained in the second process gas.

In Step ST5, the temperature of the substrate support 11 may be 10ºC or higher and 100° C. or lower.

In Step ST5, the metal-containing deposition DP may be removed. In Step ST5, a portion of the first region R1 may also be removed.

According to MT1 above, a metal-containing deposition DP is formed on the first region R1 in Step ST2. As a result, in Step ST3, it is possible to improve the etching selectivity of the second region R2 to the first region R1. Further, in Step ST4, a metal-containing deposition DP is formed on the first region R1. As a result, in Step ST5, it is possible to improve the etching selectivity of the third region R3 to the first region R1.

Further, according to MT1 above, it is possible to suppress the tapering of the openings formed in the second region R2 and the third region R3. That is, it is possible to increase the proportion of a critical dimension (CD) at a lower end (interface between the third region R3 and the underlying region UR) of the opening to a CD at an upper end (interface between the first region R1 and the second region R2) of the opening.

Further, according to MT1 above, when the metal-containing deposition DP is formed on the first region R1 in Step ST4, or when the metal-containing deposition DP is removed in Step ST5, metal atoms contained in the metal-containing deposition DP are supplied to the surface of the third region R3, and silicon atoms in a portion of the third region R3 are substituted with the metal atoms. Since the atomic weight of metal is more than the atomic weight of silicon, a portion in which some of silicon atoms are substituted with metal atoms in the third region R3 becomes chemically unstable. When the third region R3 contains oxygen in addition to silicon, the bonding energy between metal and oxygen is lower than the bonding energy between silicon and oxygen. Thus, the portion is easily etched. As a result, it is possible to improve the etching rate of the third region R3 in Step ST5.

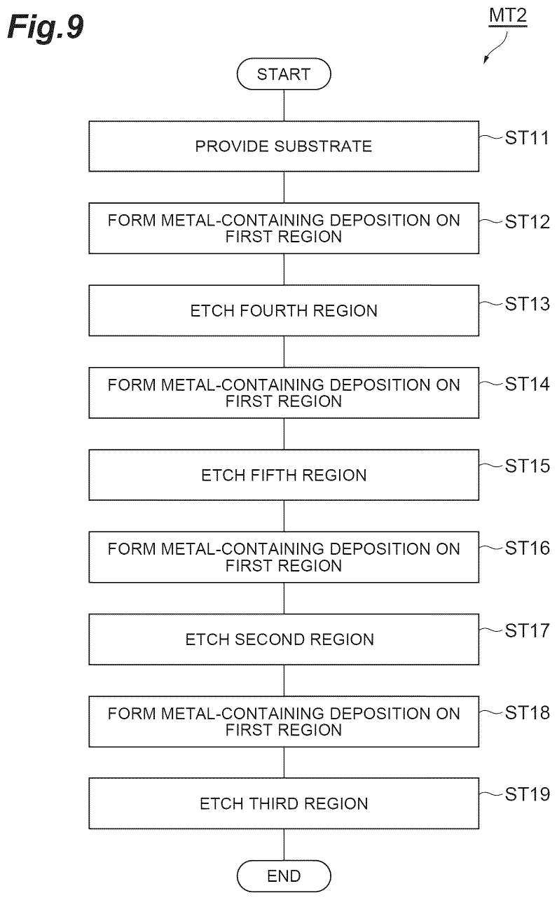

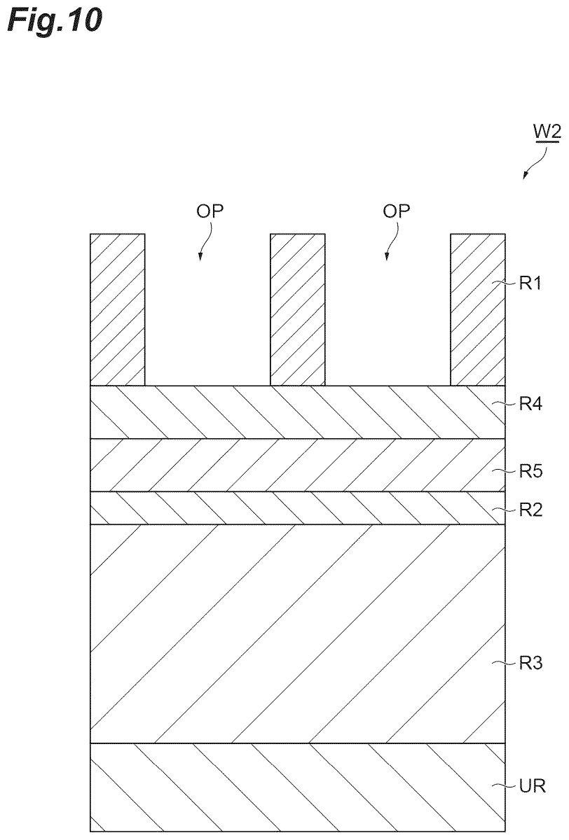

FIG. 9 is a flowchart illustrating an etching method according to another exemplary embodiment. An etching method MT2 (referred to as a “method MT2” below) illustrated in FIG. 9 may be performed by the plasma processing apparatus 1 in an embodiment. The method MT2 may be applied to a substrate W2 in FIG. 10.

FIG. 10 is a cross-sectional view of an example of a substrate to which the method of FIG. 9 may be applied. As illustrated in FIG. 10, the substrate W2 includes a fourth region R4 and a fifth region R5 in addition to the first region R1, the second region R2, the third region R3, and the underlying region UR. The fourth region R4 may be located between the first region R1 and the second region R2. The fifth region R5 may be located between the fourth region R4 and the second region R2. In the substrate W2, the first region R1, the fourth region R4, the fifth region R5, the second region R2, the third region R3, and the underlying region UR may be arranged in the downward direction in this order.

The fourth region R4 contains a fourth material. The fourth material may contain silicon and nitrogen. The fourth material may contain silicon nitride (SiNₓ). The fourth material may be different from the second material and may be the same as the second material. The fourth region R4 may be a silicon nitride film. An example of the thickness of the fourth region R4 may be equal to the example of the thickness of the second region R2 in the substrate W1 in FIG. 4.

The fifth region R5 contains a fifth material. The fifth material may be different from the fourth material. The fifth material may contain silicon and oxygen. The fifth material may contain silicon oxide (SiOₓ). The fifth material may be different from the third material and may be the same as the third material. The fifth region R5 may be a silicon oxide film. An example of the thickness of the fifth region R5 may be equal to the example of the thickness of the third region R3 in the substrate W1 in FIG. 4.

An example of the thickness of the second region R2 of the substrate W2 may be equal to the example of the thickness of the second region R2 in the substrate W1 in FIG. 4, or may be 10 nm or more and 100 nm or less. An example of the thickness of the third region R3 of the substrate W2 may be equal to the example of the thickness of the third region R3 in the substrate W1 in FIG. 4.

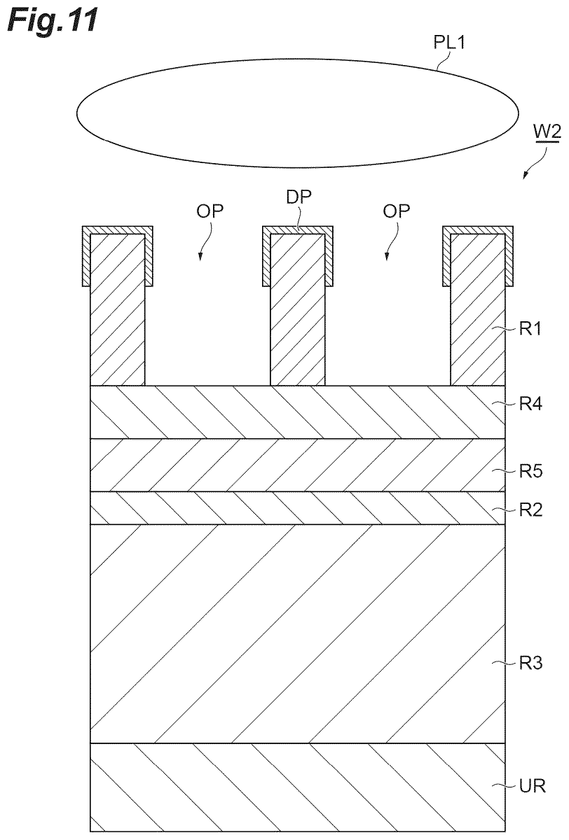

The method MT2 will be described below with reference to FIGS. 9 to 18 by using, as an example, the case where the method MT2 is applied to the substrate W2 by using a plasma processing apparatus 1 in the above-described embodiment. FIGS. 11 to 18 are cross-sectional views illustrating steps of an etching method according to another exemplary embodiment. When the plasma processing apparatus 1 is used, the method MT2 may be performed in the plasma processing apparatus 1 in a manner that a controller 2 controls each unit of the plasma processing apparatus 1. In the method MT2, as illustrated in FIG. 2, the substrate W2 is processed instead of the substrate W on a substrate support 11 disposed in a plasma processing chamber 10.

As illustrated in FIG. 9, the method MT2 may include Steps ST11 to ST19. Steps ST11 to ST19 may be performed in order. The method MT2 may not include Step ST12, may not include Step ST14, or may not include Step ST18. The method MT2 does not need to include at least one of Step ST12, Step ST14, Step ST16, or Step ST18.

### (Step ST11)

In Step ST11, the substrate W2 illustrated in FIG. 10 is provided. The substrate W2 may be supported by the substrate support 11 in the plasma processing chamber 10.

### (Step ST12)

In Step ST12, as illustrated in FIG. 11, a metal-containing deposition DP is formed on the first region R1 by using first plasma PL1 generated from a first process gas. The supply of the first process gas may be stopped when Step ST12 is ended. Step ST12 may be performed in the similar manner as Step ST2.

### (Step ST13)

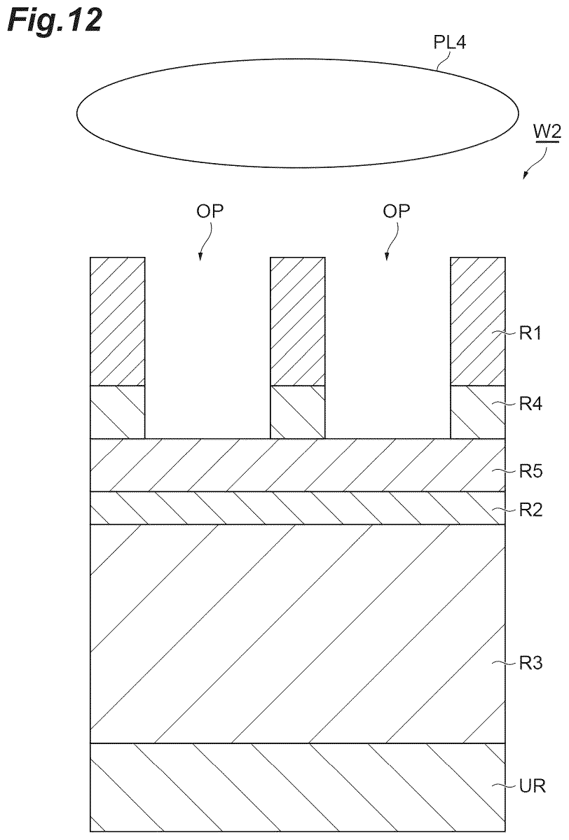

In Step ST13, as illustrated in FIG. 12, the fourth region R4 is etched via the opening OP by using fourth plasma PL4 generated from the fourth process gas. As a result, an opening is formed in the fourth region R4. The supply of the fourth process gas may be stopped when Step ST13 is ended. Step ST13 may be performed as follows. First, the gas supply 20 supplies the fourth process gas into the plasma processing chamber 10. Then, the plasma generator 12 generates the fourth plasma PL4 from the fourth process gas in the plasma processing chamber 10. The controller 2 controls the gas supply 20 and the plasma generator 12 such that the fourth region R4 is etched with the fourth plasma PL4.

The fourth process gas may be the same process gas as the second process gas, or may be a process gas different from the second process gas. An example of the fourth process gas may be the same as the example of the second process gas. In Step ST13, the fourth region R4 may be etched via the opening OP by using the second plasma PL2 generated from the second process gas.

### (Step ST14)

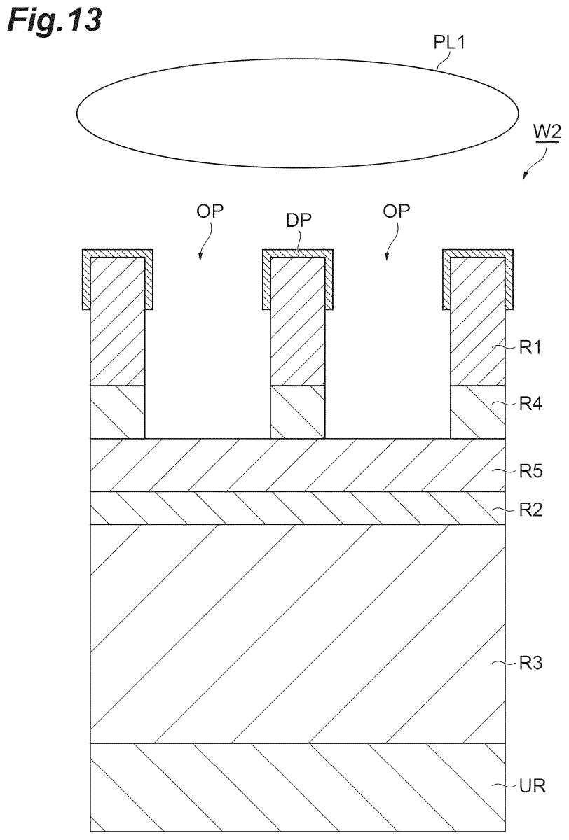

In Step ST14, as illustrated in FIG. 13, a metal-containing deposition DP is formed on the first region R1 by using first plasma PL1 generated from a first process gas. The supply of the first process gas may be stopped when Step ST14 is ended. Step ST14 may be performed in the similar manner as Step ST2.

### (Step ST15)

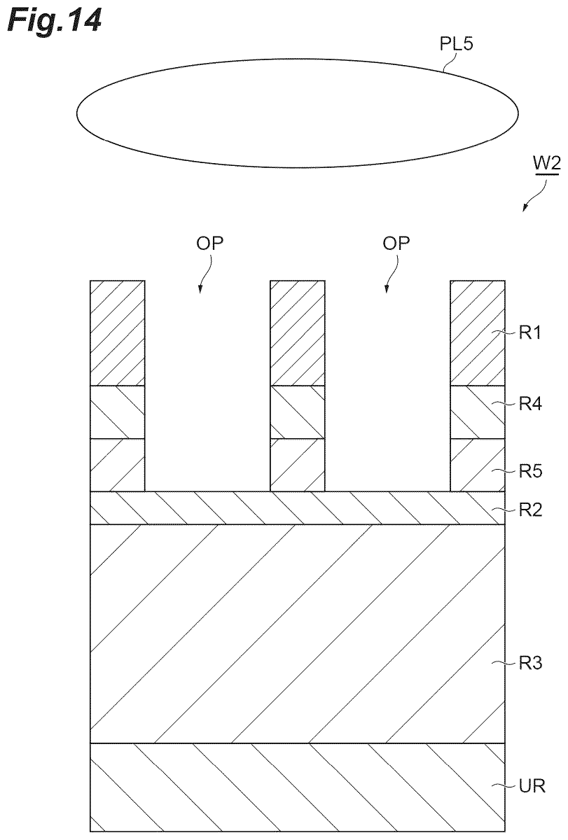

In Step ST15, as illustrated in FIG. 14, the fifth region R5 is etched via the opening OP by using fifth plasma PL5 generated from the fifth process gas. As a result, an opening is formed in the fifth region R5. The supply of the fifth process gas may be stopped when Step ST15 is ended. Step ST15 may be performed as follows. First, the gas supply 20 supplies the fifth process gas into the plasma processing chamber 10. Then, the plasma generator 12 generates the fifth plasma PL5 from the fifth process gas in the plasma processing chamber 10. The controller 2 controls the gas supply 20 and the plasma generator 12 such that the fifth region R5 is etched with the fifth plasma PL5.

The fifth process gas may be the same process gas as the third process gas, or may be a process gas different from the third process gas. An example of the fifth process gas may be the same as the example of the third process gas. In Step ST15, the fifth region R5 may be etched via the opening OP by using the third plasma PL3 generated from the third process gas.

### (Step ST16)

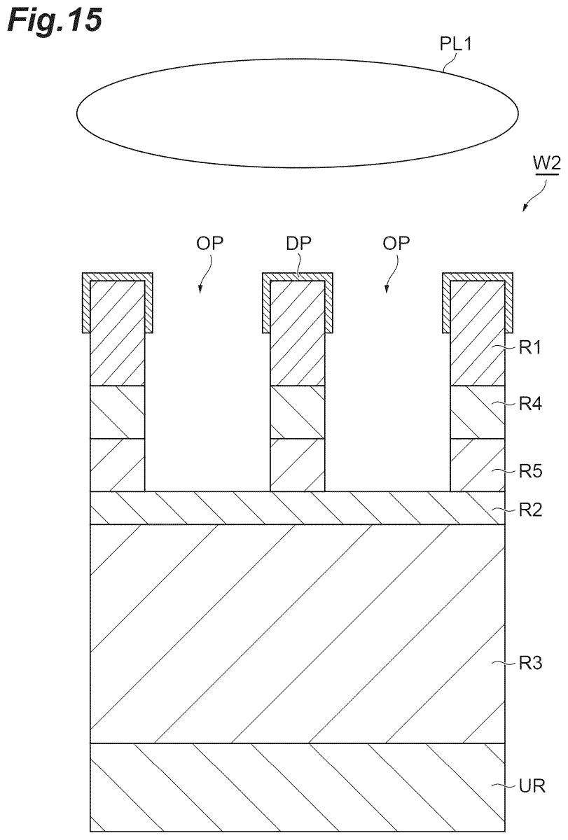

In Step ST16, as illustrated in FIG. 15, a metal-containing deposition DP is formed on the first region R1 by using first plasma PL1 generated from a first process gas. The supply of the first process gas may be stopped when Step ST16 is ended. Step ST16 may be performed in the similar manner as Step ST2.

### (Step ST17)

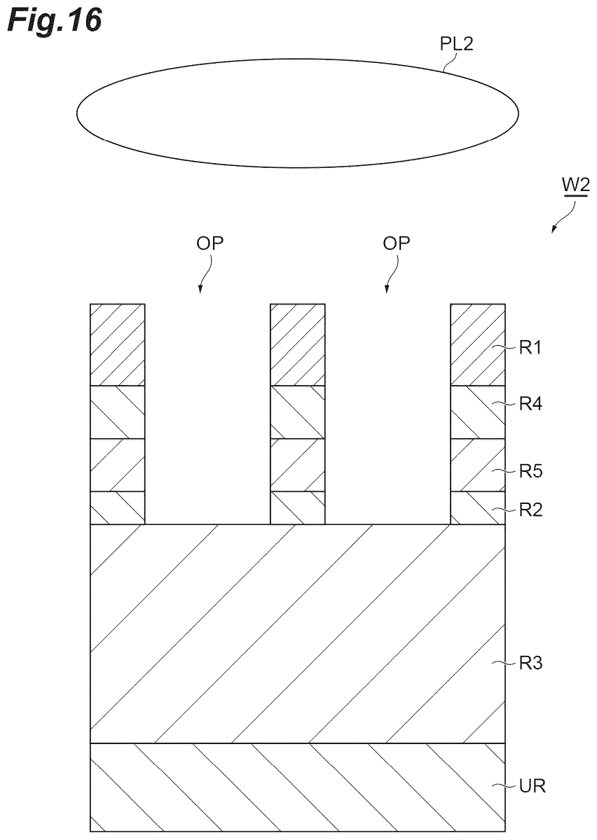

In Step ST17, as illustrated in FIG. 16, the second region R2 is etched via the opening OP by using second plasma PL2 generated from the second process gas. As a result, an opening is formed in the second region R2. The supply of the second process gas may be stopped when Step ST17 is ended. Step ST17 may be performed in the similar manner as Step ST3.

### (Step ST18)

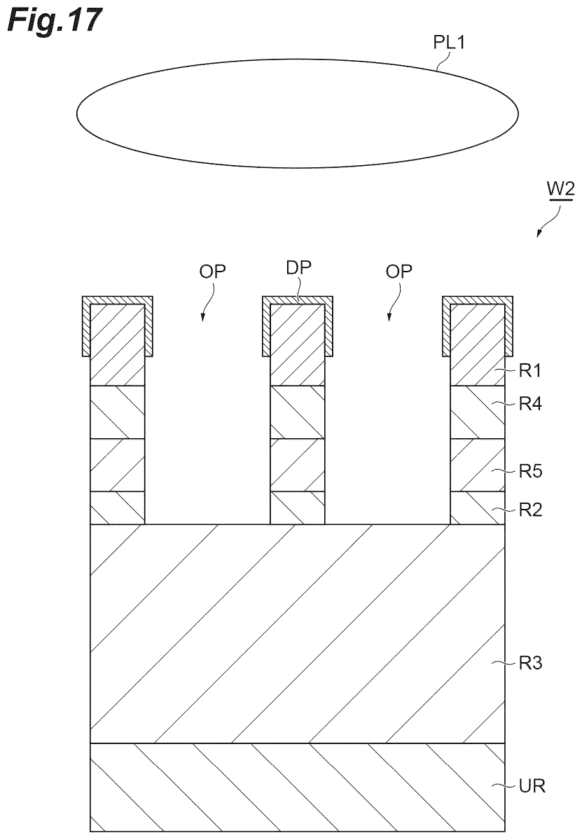

In Step ST18, as illustrated in FIG. 17, a metal-containing deposition DP is formed on the first region R1 by using first plasma PL1 generated from a first process gas. The supply of the first process gas may be stopped when Step ST18 is ended. Step ST18 may be performed in the similar manner as Step ST2.

### (Step ST19)

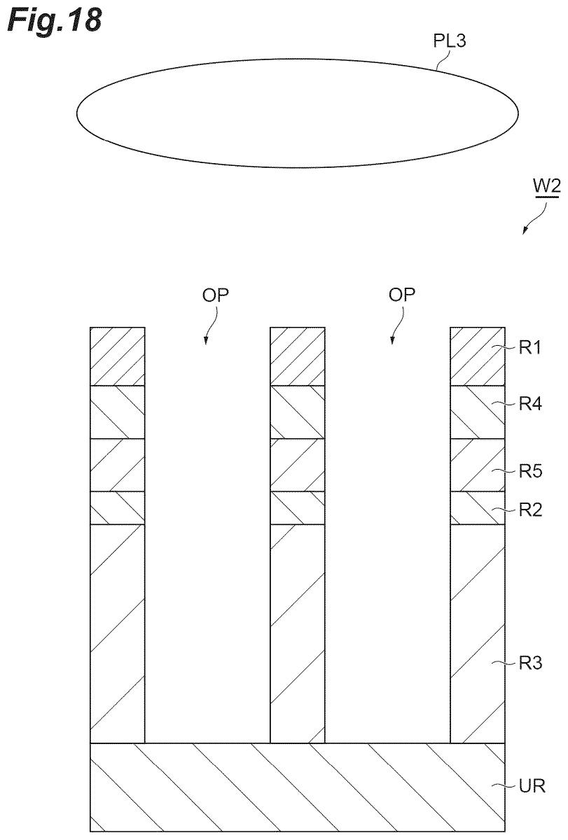

In Step ST19, as illustrated in FIG. 18, the third region R3 is etched via the opening OP by using the third plasma PL3 generated from the third process gas. As a result, an opening is formed in the third region R3. The supply of the third process gas may be stopped when Step ST19 is ended. Step ST19 may be performed in the similar manner as Step ST5.

According to MT2 above, a metal-containing deposition DP is formed on the first region R1 in Step ST12. As a result, in Step ST13, it is possible to improve the etching selectivity of the fourth region R4 to the first region R1. In Step ST14, a metal-containing deposition DP is formed on the first region R1. As a result, in Step ST15, it is possible to improve the etching selectivity of the fifth region R5 to the first region R1. In Step ST16, a metal-containing deposition DP is formed on the first region R1. As a result, in Step ST17, it is possible to improve the etching selectivity of the second region R2 to the first region R1. In Step ST18, a metal-containing deposition DP is formed on the first region R1. As a result, in Step ST19, it is possible to improve the etching selectivity of the third region R3 to the first region R1.

Further, according to MT2 above, it is possible to suppress the tapering of the openings formed in the second region R2, the third region R3, the fourth region R4, and the fifth region R5. That is, it is possible to increase the proportion of the CD at the lower end (interface between the third region R3 and the underlying region UR) of the opening to the CD at the upper end (interface between the first region R1 and the fourth region R4) of the opening.

Further, according to MT2 above, when the metal-containing deposition DP is formed on the first region R1 in Step ST14, or when the metal-containing deposition DP is removed in Step ST15, metal atoms contained in the metal-containing deposition DP are supplied to the surface of the fifth region R5, and silicon atoms in the portion of the fifth region R5 are substituted with the metal atoms. Similarly, when the metal-containing deposition DP is formed on the first region R1 in Step ST18, or when the metal-containing deposition DP is removed in Step ST19, metal atoms contained in the metal-containing deposition DP are supplied to the surface of the third region R3, and silicon atoms in a portion of the third region R3 are substituted with the metal atoms. Since the atomic weight of metal is more than the atomic weight of silicon, a portion in which some of silicon atoms are substituted with metal atoms in the fifth region R5 and the third region R3 becomes chemically unstable. When the fifth region R5 and the third region R3 contains oxygen in addition to silicon, the bonding energy between metal and oxygen is lower than the bonding energy between silicon and oxygen. Thus, the portion is easily etched. As a result, it is possible to improve the etching rate of the fifth region R5 in Step ST15, and it is possible to improve the etching rate of the third region R3 in Step ST19.

Various experiments performed for evaluating the methods MT1 and MT2 are described below. The experiments described below do not limit the present disclosure.

### (First Experiment)

In a first experiment, a substrate including a mask having an opening, a silicon-containing film below the mask, and an underlying region below the silicon-containing film was provided. The silicon-containing film includes a silicon nitride film and a silicon oxide film. Thereafter, a tungsten-containing deposition was formed on the mask by using plasma generated from a process gas containing a WF₆ gas, a CH₄ gas, and an Ar gas. Thereafter, the silicon-containing film was etched via the opening of the mask. As a result, an opening was formed in the silicon-containing film. The formation of the tungsten-containing deposition was confirmed by using an energy dispersive X-ray spectroscopy (EDX) of a transmission electron microscopy (TEM) device.

### (Second Experiment)

A second experiment was performed in the same manner as the first experiment, except that the tungsten-containing deposition was not formed.

### (Results of First Experiment and Second Experiment)

In each of the first experiment and the second experiment, the thickness of the mask was measured by observing the cross-section of the substrate after the etching. As a result, it was understood that the amount of reduction of the mask due to etching was reduced by the formation of the tungsten-containing deposition.

In each of the first experiment and the second experiment, the CD of the opening formed in the silicon-containing film was measured by observing the cross-section of the substrate after the etching. Specifically, the CD (top CD) at the upper end (the interface between the mask and the silicon-containing film) of the opening and the CD (bottom CD) at the lower end (the interface between the silicon-containing film and the underlying film) of the opening were measured. In the first experiment, the proportion of bottom CD to top CD was 73%. On the other hand, in the second experiment, the proportion of bottom CD to top CD was 66%. Therefore, it is understood that the formation of the tungsten-containing depositions increases the proportion of bottom CD to top CD, that is, the tapering of the opening is suppressed.

### (Third Experiment)

In a third experiment, a substrate including a silicon oxide film was provided. A tungsten-containing deposition was formed on the silicon oxide film by using plasma generated from a process gas containing a WF₆ gas, a CH₄ gas, and an Ar gas. Then, the silicon oxide film was etched.

### (Fourth Experiment)

A fourth experiment was performed in the same manner as the third experiment, except that the tungsten-containing deposition was not formed.

### (Results of Third Experiment and Fourth Experiment)

In each of the third experiment and the fourth experiment, the thickness of the silicon oxide film was measured by observing the cross-section of the substrate after the etching. As a result, it was understood that the etching amount of the silicon oxide film in the case of forming the tungsten-containing film was larger than the etching amount of the silicon oxide film in the case of not forming the tungsten-containing film.

### (Fifth Experiment)

In the fifth experiment, a substrate including a polysilicon film was provided. A tungsten-containing deposition was formed on the polysilicon film by using plasma generated from a process gas containing a WF₆ gas, a CH₄ gas, and an Ar gas. Then, the polysilicon film was etched.

### (Sixth Experiment)

A sixth experiment was performed in the same manner as the fifth experiment, except that the tungsten-containing deposition was not formed.

### (Results of Fifth Experiment and Sixth Experiment)

In each of the fifth experiment and the sixth experiment, the thickness of the polysilicon film was measured by observing the cross-section of the substrate after the etching. As a result, it was understood that the etching amount of the polysilicon film when the tungsten-containing film was formed was smaller than the etching amount of the polysilicon film when the tungsten-containing film was not formed.

According to the present disclosure, it is possible to improve etching selectivity.

Although the various exemplary embodiments have been described above, various additions, omissions, substitutions, and changes may be made without being limited to the exemplary embodiments described above. Other embodiments can be formed by combining elements in different embodiments.

Here, the various exemplary embodiments included in the present disclosure are described in [E1] to [E19] below.

[E1] An etching method comprising:
(a) providing a substrate including a first region and a second region below the first region, the first region containing a first material and including an opening, the second region containing a second material different from the first material, the second material containing silicon;
(b) forming a metal-containing deposition on the first region by using first plasma generated from a first process gas containing halogen, metal, and at least one of carbon or hydrogen; and
(c) after (b), etching the second region via the opening by using second plasma generated from a second process gas different from the first process gas.

According to the etching method [E1], it is possible to improve etching selectivity in (c).

[E2] The etching method according to [E1], wherein
the substrate further includes a third region below the second region,
the third region contains a third material different from the first material and the second material, the third material containing silicon, and
the etching method further comprises (d) after (c), etching the third region via the opening by using third plasma generated from a third process gas different from the first process gas and the second process gas.

[E3] The etching method according to [E1], wherein
(b) is performed between (c) and (d).

According to the etching method [E3], it is possible to improve etching selectivity in (d).

[E4] The etching method according to any one of [E1] to [E3], wherein
the metal includes at least one of molybdenum or tungsten.

[E5] The etching method according to [E4], wherein
the first process gas contains at least one metal-containing gas among a molybdenum halide gas or a tungsten halide gas.

[E6] The etching method according to [E5], wherein
the molybdenum halide gas includes at least one selected from the group consisting of a MoF₃ gas, a MoF₅ gas, a MoF₆ gas, a MoCl₆ gas, a MoBr₆ gas, a MoCl₂ gas, a MoBr₂ gas, a MoCl₅ gas, a Mo₃Br₅ gas, a Mo₆Cl₈ gas, a Mo₆Cl₁₂ gas, a Mo₆Br₁₂ gas, and a Mo₆Cl₁₄ gas.

[E7] The etching method according to [E5], wherein
the tungsten halide gas includes at least one selected from the group consisting of a WF₆ gas, a WCl₆ gas, a WBr₆ gas, and a WF₅Cl gas.

[E8] The etching method according to any one of [E5] to [E7], wherein
a proportion of a flow rate of the metal-containing gas to a total flow rate of the first process gas is 10 vol % or less.

[E9] The etching method according to any one of [E1] to [E8], wherein
the first process gas contains at least one of a hydrocarbon gas or a hydrofluorocarbon gas.

[E10] The etching method according to any one of [E1] to [E9], wherein
the second process gas contains a hydrogen-containing gas.

[E11] The etching method according to [E2] or any one of [E3] to [E10] depending on [E2], wherein
the third process gas does not contain a hydrogen-containing gas.

[E12] The etching method according to any one of [E1] to [E11], wherein
the second material contains silicon nitride.

[E13] The etching method according to [E2] or any one of [E3] to [E12] depending on [E2], wherein
the third material contains silicon oxide.

[E14] The etching method according to [E2] or any one of [E3] to [E13] depending on [E2], wherein
the third region has a thickness of 100 nm or more.

[E15] The etching method according to any one of [E1] to [E14], wherein
in (a), the substrate further includes a fourth region between the first region and the second region and a fifth region between the fourth region and the second region, the fourth region containing a fourth material, the fifth region containing a fifth material, and
the etching method further comprises
   (e) between (b) and (c), etching the fourth region via the opening by using fourth plasma generated from a fourth process gas, and
   (f) between (e) and (c), etching the fifth region via the opening by using fifth plasma generated from a fifth process gas different from the fourth process gas.

[E16] The etching method according to [15], wherein
(b) is performed at least one of a period between (e) and (f), or a period between (f) and (c).

According to the etching method [E16], it is possible to improve etching selectivity in at least one of (e) or (f).

[E17] The etching method according to [15] or [16], wherein
the fourth material contains silicon nitride.

[E18] The etching method according to any one of [E5] to [E17], wherein
the fifth material contains silicon oxide.

[E19] A plasma processing apparatus comprising:
a chamber;
a substrate support for supporting a substrate in the chamber, the substrate including a first region and a second region below the first region, the first region containing a first material and including an opening, the second region containing a second material different from the first material, the second region containing silicon;
a gas supply configured to supply a first process gas and a second process gas into the chamber, the first process gas containing halogen, metal, and at least one of carbon or hydrogen, the second process gas being different from the first process gas;
a plasma generator configured to generate first plasma from the first process gas and second plasma from the second process gas in the chamber; and
a controller,
wherein the controller is configured to control the gas supply and the plasma generator to execute
   (b) forming a metal-containing deposition on the first region by using the first plasma, and
   (c) after (b), etching the second region via the opening by using the second plasma.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) providing a substrate including a first region and a second region below the first region, the first region containing a first material and including an opening, the second region containing a second material different from the first material, the second material containing silicon;
(b) forming a metal-containing deposition on the first region by using first plasma generated from a first process gas containing halogen, metal, and at least one of carbon or hydrogen; and
(c) after (b), etching the second region via the opening by using second plasma generated from a second process gas different from the first process gas.

2. The etching method according to claim 1, wherein
the substrate further includes a third region below the second region,
the third region contains a third material different from the first material and the second material, the third material containing silicon, and
the etching method further comprises (d) after (c), etching the third region via the opening by using third plasma generated from a third process gas different from the first process gas and the second process gas.

3. The etching method according to claim 2, wherein
(b) is performed between (c) and (d).

4. The etching method according to claim 1, wherein
the metal includes at least one of molybdenum or tungsten.

5. The etching method according to claim 4, wherein
the first process gas contains at least one metal-containing gas among a molybdenum halide gas or a tungsten halide gas.

6. The etching method according to claim 5, wherein
the molybdenum halide gas includes at least one selected from the group consisting of a MoF₃ gas, a MoF₅ gas, a MoF₆ gas, a MoCl₆ gas, a MoBr₆ gas, a MoCl₂ gas, a MoBr₂ gas, a MoCl₅ gas, a Mo₃Br₅ gas, a Mo₆Cl₈ gas, a Mo₆Cl₁₂ gas, a Mo₆Br₁₂ gas, and a Mo₆Cl₁₄ gas.

7. The etching method according to claim 5, wherein
the tungsten halide gas includes at least one selected from the group consisting of a WF₆ gas, a WCl₆ gas, a WBr₆ gas, and a WF₅Cl gas.

8. The etching method according to claim 5, wherein
a proportion of a flow rate of the metal-containing gas to a total flow rate of the first process gas is 10 vol % or less.

9. The etching method according to claim 1, wherein
the first process gas contains at least one of a hydrocarbon gas or a hydrofluorocarbon gas.

10. The etching method according to claim 1, wherein
the second process gas contains a hydrogen-containing gas.

11. The etching method according to claim 2, wherein
the third process gas does not contain a hydrogen-containing gas.

12. The etching method according to claim 1, wherein
the second material contains silicon nitride.

13. The etching method according to claim 2, wherein
the third material contains silicon oxide.

14. The etching method according to claim 2, wherein
the third region has a thickness of 100 nm or more.

15. The etching method according to claim 1, wherein
in (a), the substrate further includes a fourth region between the first region and the second region and a fifth region between the fourth region and the second region, the fourth region containing a fourth material, the fifth region containing a fifth material, and
the etching method further comprises
(e) between (b) and (c), etching the fourth region via the opening by using fourth plasma generated from a fourth process gas, and
(f) between (e) and (c), etching the fifth region via the opening by using fifth plasma generated from a fifth process gas different from the fourth process gas.

16. The etching method according to claim 15, wherein
(b) is performed at least one of a period between (e) and (f), or a period between (f) and (c).

17. The etching method according to claim 15, wherein
the fourth material contains silicon nitride.

18. The etching method according to claim 15, wherein
the fifth material contains silicon oxide.

19. A plasma processing apparatus comprising:
a chamber;
a substrate support for supporting a substrate in the chamber, the substrate including a first region and a second region below the first region, the first region containing a first material and including an opening, the second region containing a second material different from the first material, the second region containing silicon;
a gas supply configured to supply a first process gas and a second process gas into the chamber, the first process gas containing halogen, metal, and at least one of carbon or hydrogen, the second process gas being different from the first process gas;
a plasma generator configured to generate first plasma from the first process gas and second plasma from the second process gas in the chamber; and
a controller,
wherein the controller is configured to control the gas supply and the plasma generator to execute
(b) forming a metal-containing deposition on the first region by using the first plasma, and
(c) after (b), etching the second region via the opening by using the second plasma.
